(19) United States
(12) Patent Application Publication
(10) Pub. No.: US 2017/0077362 A1
(43) Pub. Date: Mar. 16, 2017

(54) LIGHT-EMITTING APPARATUS AND ILLUMINATION APPARATUS

(71) Applicant: Panasonic Intellectual Property Management Co., Ltd., Osaka (JP)

(72) Inventors: Toshifumi OGATA, Osaka (JP); Koji Omura, Osaka (JP)

(21) Appl. No.: 15/258,560

(22) Filed: Sep. 7, 2016

(30) Foreign Application Priority Data
Sep. 10, 2015 (JP) 2015-178966

(51) Int. Cl. H01L 33/50; H01L 33/56; H01L 27/15

(52) U.S. Cl. CPC H01L 33/507; H01L 27/156; H01L 33/56

(57) ABSTRACT

A light-emitting apparatus includes: a substrate; a first light-emitting element (a first LED chip) mounted on the substrate; a second light-emitting element (a second LED chip) having a light-emission peak wavelength longer than a light-emission peak wavelength of the first light-emitting element; a first sealing member sealing the first light-emitting element and containing a phosphor that emits fluorescent light when illuminated by light from the first light-emitting element; and a second sealing member sealing the second light-emitting element and having at least a portion between the first sealing member arid the second light-emitting element. The second scaling member has an absorbance lower than an absorbance of the first sealing member with respect to light emitted from the second light-emitting element.

### CROSS REFERENCE TO RELATED APPLICATION

This application claims the benefit of priority of Japanese Patent Application Number 2015-178966 filed on Sep. 10, 2015, the entire content of which is hereby incorporated by reference.

### BACKGROUND

### 1. Technical Field

The present disclosure relates to a light-emitting apparatus in which a light-emitting element is mounted on a substrate, and to an illumination apparatus including the light-emitting apparatus.

### 2. Description of the Related Art

As a light-emitting apparatus that emits white light, a light-emitting apparatus in which a blue-based light-emitting element (hereinafter “a blue element”) is combined with a yellow-based phosphor and a red phosphor is known (see Japanese Unexamined Patent Application Publication No. 2007-116117). In the light-emitting apparatus disclosed in Japanese Unexamined Patent Application Publication No. 2007-116117, a blue element is sealed with a sealing resin. In the sealing resin, a yellow-based phosphor that absorbs blue light emitted from the blue element and emits yellow light or orange light and a red phosphor that absorbs the blue light and emits red light are dispersed. In the above light-emitting apparatus, blue light emitted from the blue element, yellow light or orange light emitted from the yellow-based phosphor, and red light emitted from the red phosphor are mixed to generate white light.

### SUMMARY

Recent studies include a system of providing a light-emitting apparatus with a red-based light-emitting element (hereinafter “a red element”) to increase light-emission efficiency of red light. In this case, it is desired that red light emitted from the red element be not absorbed by a sealing resin, but be output from the sealing resin with properties maintained since the light emission from the red element in practice, however, when red light passes through a sealing resin, the red light is absorbed by the sealing resin and thus weakened, resulting in a failure to obtain desired color rendering properties.

Thus, in the case of using a light-emitting element that is not intended to excite a phosphor, it is problematic that when light emitted from the light-emitting element passes through a sealing resin, the light is absorbed and thus weakened, resulting in a failure to obtain desired color rendering properties.

One of the objectives of the present disclosure is to provide a light-emitting apparatus and an illumination apparatus that are capable of reducing the decrease in light-emission intensity of light that is not intended to excite a phosphor.

A light-emitting apparatus according to an aspect of the present disclosure includes: a substrate: a first light-emitting element mounted on the substrate; a second light-emitting element, having a light-emission peak wavelength longer than a light-emission peak wavelength of the first light-emitting element; a first sealing ember sealing the first light-emitting element and containing a phosphor that emits fluorescent light when illuminated by light from the first light-emitting element; and a second sealing member sealing the second light-emitting element and having at least a portion between the first sealing member and the second light-emitting element, wherein the second sealing member has an absorbance lower than an absorbance of the first sealing member with respect to light emitted from the second light-emitting element.

A light-emitting apparatus according to an aspect of the present disclosure includes: a substrate; first light-emitting elements disposed on the substrate, the first light emitting elements emitting first light having a first light-emission peak wavelength; second light-emitting elements disposed on the substrate, the second light-emitting elements emitting second light having a second light-emission peak wavelength longer than the first light-emission peak wavelength; a first sealing member sealing the first light-emitting elements and containing a phosphor that emits fluorescent light when illuminated by the first light; and second sealing members sealing the second light-emitting elements, respectively, wherein the first seaming member covers at least a portion of each of the second sealing members and is not in contact with second light-emitting elements, and the second sealing members have an absorbance lower than an absorbance of the first sealing member with respect to the second light.

A light-emitting apparatus according to an aspect of the present disclosure includes: a substrate; a first light-emitting element disposed on the substrate, the first light emitting element emitting first light having a first light-emission peak wavelength; a second light-emitting element disposed on the substrate, the second light-emitting element emitting second light having a second light-emission peak wavelength longer than the first light-emission peak wavelength; a first sealing member sealing the first light-emitting element and containing a phosphor that emits fluorescent light when illuminated by the first light; and a second sealing member sealing the second light-emitting element, wherein at least a portion of the second sealing member is disposed between the first sealing member and the second light-emitting element, and the second sealing member includes a transparent resin that does not contain the phosphor.

An illumination apparatus according to another aspect of the present disclosure includes the above-described light-emitting apparatus.

According to the present disclosure, it is possible to reduce the decrease in light-emission intensity of a light-emitting element that is not intended, to excite a phosphor.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view of an external appearance of a light-emitting apparatus according to Embodiment 1;

FIG. 2 is a plan view of a light-emitting apparatus according to Embodiment 1;

FIG. 3 is a plan view illustrating the internal structure of a light-emitting apparatus according to Embodiment 1;

FIG. 4 is a cross-sectional view of a light-emitting apparatus, taken along line IV-IV in FIG. 2;

FIG. 5 is a flowchart of a method of manufacturing a light-emitting apparatus according to Embodiment 1;

FIG. 6A is a cross-sectional view illustrating one step in a method of manufacturing a light-emitting apparatus according to Embodiment 1;

FIG. 6B is a cross-sectional view illustrating one step in a method of manufacturing a light-emitting apparatus according to Embodiment 1;

FIG. 6C is a cross-sectional view illustrating one step in a method of manufacturing a light-emitting apparatus according to Embodiment 1;

FIG. 6D is a cross-sectional view illustrating one step in a method of manufacturing a light-emitting apparatus according to Embodiment 1;

FIG. 6E is a cross-sectional view illustrating one step in a method of manufacturing a light-emitting apparatus according to Embodiment 1;

FIG. 7 is a cross-sectional view of a light-emitting apparatus according to a variation, schematically illustrating a configuration thereof;

FIG. 8 is a cross-sectional view of an illumination apparatus according to Embodiment 2; and

FIG. 9 is a perspective view of external appearances of an illumination apparatus and peripheral members thereof according to Embodiment 2.

### DETAILED DESCRIPTION OF THE EMBODIMENTS

Hereinafter, a light-emitting apparatus, etc., according to embodiments are described with reference to the Drawings. Note that each of the embodiments described below shows a general or specific example. The numerical values, shapes, materials, structural elements, the arrangement and connection of the structural elements, steps, the processing order of the steps, etc., shown in the following embodiments are mere examples, and therefore do not limit the present disclosure. As such, among the structural elements in the following embodiments, those not recited in any one of the independent claims which indicate the broadest inventive concepts are described as arbitrary structural elements.

Furthermore, the respective figures are schematic illustrations and are not necessarily precise illustrations. Additionally, in the figures, substantially identical elements are assigned the same reference signs, and there are cases where overlapping descriptions are omitted or simplified.

### Embodiment 1

### Configuration of Light-Emitting Apparatus

First, the configuration of a light-emitting apparatus according to

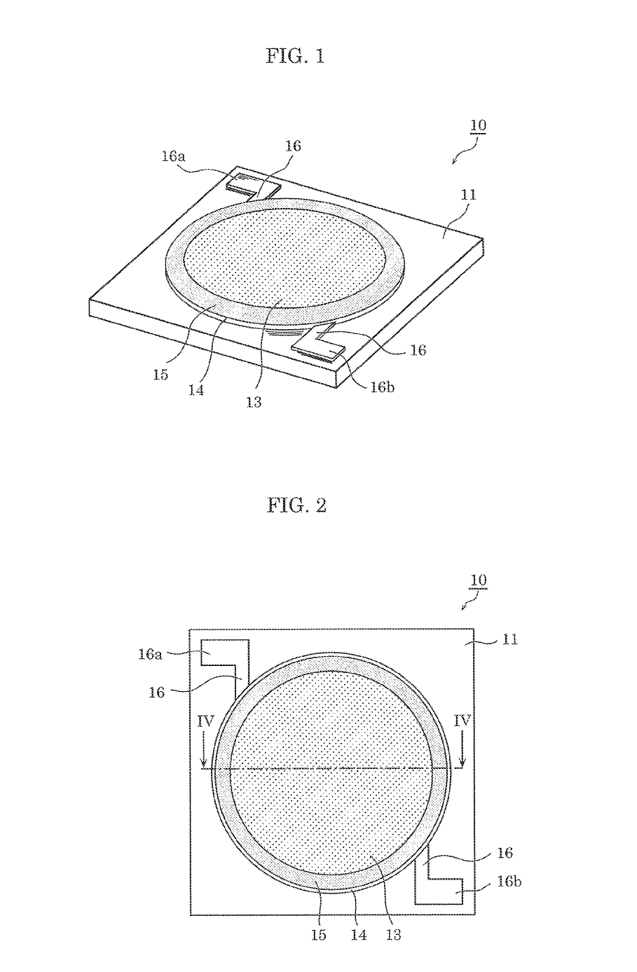

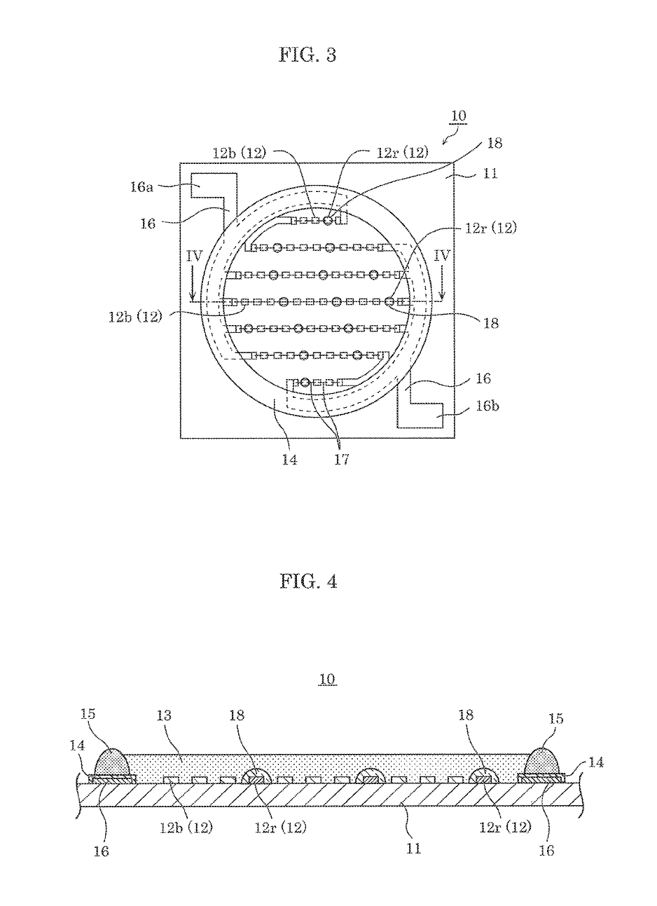

Embodiment 1 will be described with reference to the Drawings. FIG. 1 is a perspective view of an external appearance of a light-emitting apparatus according to Embodiment 1. FIG. 2 is a plan view of a light-emitting apparatus according to Embodiment 1. FIG. 3 is a plan view illustrating the internal structure of a light-emitting apparatus according to Embodiment 1.

FIG. 4 is a cross-sectional view of a light-emitting apparatus, taken along line IV-IV in FIG. 2. Note that FIG. 3 is a plan view of the light-emitting apparatus which corresponds to that illustrated in FIG. 2 and illustrates the internal structure thereof including the arrangement of LED (light-emitting diode) chips 12 and a wiring pattern with first sealing member 13 and dam member (side sealing member) 15 removed.

Light-emitting apparatus 10 according to Embodiment 1 includes substrate 11, two or more LED chips 12, first sealing member 13, second sealing member 13, buffer layer 14, and dam member 15, as illustrated in FIG. 1 to FIG. 4.

Light-emitting apparatus 10 is what is called a COB (chip-on-board) LED module in which LED chips 12 are directly mounted on substrate 11.

Substrate 11 has a wiring region in which wiring 16 is provided. Note that wiring 16 (as well as electrode 16a and electrode 16b) is metal wiring for supplying electric power to LED chips 12. Substrate 11 is, for example, a metal-based substrate or a ceramic substrate. Furthermore, substrate 11 may be a resin substrate that uses a resin as a base material.

An alumina substrate made of aluminum oxide (alumina), an aluminum nitride substrate made of aluminum nitride, or the like is used as the ceramic substrate. An aluminum alloy substrate, an iron alloy substrate, a copper alloy substrate, or the like, the surface of which is coated with an insulating film, for example, is used as the metal-based substrate. A glass epoxy substrate made of glass fiber and an epoxy resin is used as the resin substrate, for example.

Note that a substrate having a high optical reflectivity (for example, an optical reflectivity of 90% or higher), for example, may be used as substrate 11. Using a substrate having a high optical reflectivity as substrate 11 allows light emitted by LED chips 12 to be reflected off the surface of substrate 11. This results in an increase in the light extraction rate of light-emitting apparatus 10. Examples of the substrate include a white ceramic substrate that uses alumina as a base material.

Alternatively, a light-transmissive substrate having high light transmittance may he used as substrate 11. Examples of the substrate include a light-transmissive ceramic substrate made of polycrystalline alumina or aluminum nitride, a clear glass substrate made of glass, a crystal substrate made of crystal, a sapphire substrate made of sapphire, or a transparent resin substrate made of a transparent resin material.

Note that substrate 11 has a rectangular shape in Embodiment 1, but may have a circular or other shape.

Two or more LED chips 12 include first LED chip 12b and second LED chip 12r as illustrated in FIG. 3.

First LED chip 12b is one example of a first light-emitting element and is an LED chip that emits first light having a first light-emission peak wavelength. Specifically, first LED chip 12b is a blue LED chip which emits blue light. For example, a gallium nitride LED chip formed using an InGaN-based material and having a light-emission, peak wavelength (a peak wavelength of the light emission spectrum) in the range from 430 nm to 480 nm is used as first LED chip 12b.

Second LED chip 12r is one example of a second light-emitting element and is an LED chip that emits second light having a second light-emission peak wavelength longer than the first light-emission peak wavelength. Specifically, second LED chip 12r is a red LED chip which emits red light. For example, a gallium nitride LED chip formed using an AlGaInP-based material and having a light-emission peak wavelength in the range from 600 nm to 660 nm is used as second LED chip 12r. Second LED chip 12r is covered with second sealing member 18, which will be described later.

A plurality of light-emitting element lines including two or more LED chips 12 are provided on substrate 11. From the structural perspective, seven light-emitting element lines are provided on substrate 11 in such a way as to be fit within the shape of a circle as illustrated in FIG. 3.

From the electrical perspective, five light-emitting element lines each including 12 LED chips 12 connected in series are provided on substrate 11. These five light-emitting element lines are connected in parallel and emit light with electric power supplied between electrode 16a and electrode 16b.

One light-emitting element line, when viewed from the electrical perspective, includes nine first LED chips 12b and three second LED chips 12r. This means that the ratio of first LED chips 12b to second LEI) chips 12r is 3 to 1. The entire view of substrate 11 shows that first LED chips 12b and second LED chips 12r are disposed thereon in such a way that first LED chips 12b and second LED chips 12r are roughly evenly spread.

Although details are not illustrated in the Drawings, LED chips 12 are connected in series in a chip-to-chip configuration mainly by bonding wire 17 (some of LED chips 12 are connected by wiring 16). For example, gold (Au), silver (Ag), copper (Cu), or the like is used as a metal material of bonding wire 17 as well as a metal material of wiring 16, electrode 16a, and electrode 16b mentioned above.

Second sealing member 18 is a member that has light-transmitting properties and seals second LED chips 12r individually as illustrated in FIG. 3 and FIG. 4. When second sealing member 18 transmits and outputs the red light emitted from second LED chip 12r, it is desirable that second sealing member 18 emit the red light without decreasing the light-emission intensity of the red light. Therefore, second sealing member 18 is formed of a material that has an absorbance lower than an absorbance of first sealing member 13 with respect to the red light. Specifically, second sealing member 18 is formed of a light-transmissive resin material such as a transparent resin. The transparent resin ideally does not contain phosphor particles of any kind and does not have a wavelength-converting function. Note that an additive such as a dispersing agent may be added to the light-transmissive resin material so long as the absorbance of second sealing member 18 will be lower than an absorbance of first sealing member 18.

Second sealing member 18 is formed on substrate 11 so as to cover an entirety of second LED chip 12r. Specifically, second sealing member 18 is in the shape of a hemisphere that is tipped in a direction in which the light emitted from second LED chip 12r travels. Second sealing member 18 is disposed in such a way that an optical axis of second LED chip 12r passes through an apex portion of second sealing member 18. This allows the red light that has entered second sealing member 18 from second LED chip 12r to be output through a spherical surface of second sealing member 18 without being totally reflected off the spherical surface.

Note that although the case where second sealing member 18 is hemispherical is described as an example in the present embodiment, second sealing member 18 may be not in the shape of a perfect hemisphere, but being roughly hemispherical is enough. Furthermore, second sealing member 18 may have a shape other than the shape of a hemisphere.

First sealing member 13 is provided, on substrate 11 and seals two or more LED chips 12, bonding wire 17, and wiring 16. Specifically, first sealing member 13 directly seals first LED chip 12b among two or more LED chips 12. Meanwhile, first sealing member 13 seals entire second sealing member 18, resulting in sealing second LED chip 12r among two or more LED chips 12 via second sealing member 18. In other words, second sealing member 18 is in the state of being between first sealing member 13 and second LED chip 12r. Furthermore, second sealing member 18 is in the state of being fully embedded in first sealing member 13.

Furthermore, first sealing member 13 is flat in surface shape. In a plan view of substrate 11, a portion of first sealing member 13 overlapping second sealing member 18 is thinner than a portion of first sealing member 13 overlapping first LED chip 12b.

Note that first sealing member 13 is not required to be flat in surface shape and may have a curved surface.

First sealing member 13 is formed of a light-transmissive resin material containing yellow phosphor particles and green phosphor particles as a wavelength converting element. As the light-transmissive resin material, a silicone resin is used, for example, but an epoxy resin, a urea resin, or the like may be used. As green phosphor particles and yellow phosphor particles, an yttrium aluminum garnet (YAG)-based phosphor (phosphor particles) is used.

In this configuration, the wavelength of a portion of the blue light emitted from first LED chips 12b is converted by the yellow phosphor particles contained in first sealing member 13, so that the portion is transformed into yellow light. Likewise, the wavelength of a portion of the blue light emitted from first LED chips 12b is converted by the green phosphor particles contained in first sealing member 13, so that the portion is transformed into green light. On the other hand, the red light emitted from second LED chip 12r passes through second sealing member 18 and then enters first sealing member 13.

Then, the blue light not absorbed by the yellow phosphor particles and the green phosphor particles, the yellow light resulting from the wavelength conversion by the yellow phosphor particles, the green light resulting from the wavelength conversion by the green phosphor particles, and the incident red light from second LED chip 12r are diffused and mixed within first sealing member 13. Consequently, white light having improved color rendering properties is emitted from first sealing member 13.

Note that first sealing member 13 and second sealing member 18 also have a function of protecting LED chips 12 and bonding wire 17 from dust, moisture, external force, or the like.

Buffer layer 14 is an undercoat layer formed on substrate 11, for forming dam member 15. In Embodiment 1, buffer layer 14 is a glass coat layer formed by coating substrate 11 with glass.

In Embodiment 1, buffer layer 14 is formed so as to bridge the wiring region and a region other than the wiring region. Thus, on substrate 11, there are a part where buffer layer 14 is formed so as to cover the wiring region (wiring 16) (illustrated in FIG. 4) and a part where buffer layer 14 is formed directly on substrate 11.

Buffer layer 14 is provided so as to cover the pattern of wiring 16 having a substantially circular annular shape provided around two or more LED chips 12. In other words, buffer layer 14 is formed in a circular annular shape so as to surround two or more LED chips 12 in a plan view of substrate 11. The outer shape of buffer layer 14 may be a rectangular annular shape. The thickness of buffer layer 14 is in the range from about 5 μm to 50 μm. Note that the thickness of buffer layer 14 can be increased to reduce the amount of a material to be used for dam member 15.

As illustrated in FIG. 4, dam member (side sealing member) 15 is provided on the top surface of buffer layer 14 and serves to block first sealing member 13. The shape of a cross section of dam member 15 is a protruding shape with the tip pointing upward

For example, a thermosetting resin or a thermoplastic resin having an insulating property is used as darn member 15. More specifically, a silicone resin, a phenol resin, an epoxy resin, a BT (bismaleimide-triazine) resin, PPA (polyphthalamide), or the like is used as dam member 15.

It is desirable that darn member 15 have a light-reflecting property in order to increase the light extraction rate of light-emitting apparatus 10. Thus, a resin in a white color (what is called a white resin) is used as dam member 15 in Embodiment 1. Note that in order to increase the light-reflecting property of clam member 15, TiO₂, Al₂O₃, ZrO₂, MgO, and the like particles may be contained in dam member 15.

As illustrated in FIG. 2, in light-emitting apparatus 10, dam member 15 is formed in a circular annular shape so as to surround two or more LED chips 12 in a plan view of substrate 11. The region surrounded by darn member 15 is filled with first sealing member 13. With this, it is possible to increase the light extraction rate of light-emitting apparatus 10. Note that the outer shape of dam member 15 may be a rectangular annular shape as with the case of buffer layer 14.

### Method of Manufacturing Light-Emitting Apparatus

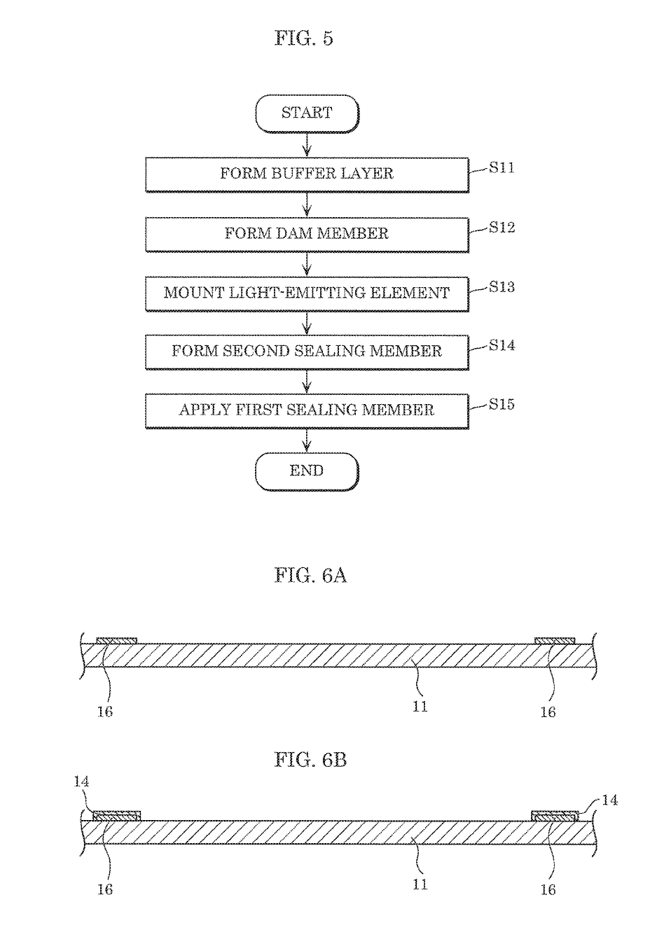

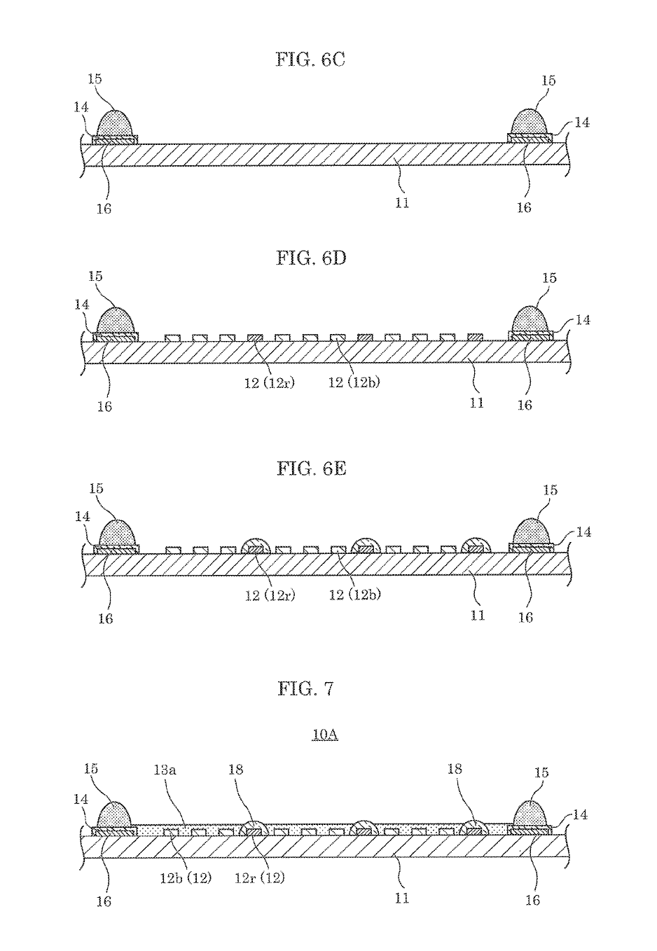

Next, a method of manufacturing light-emitting apparatus 10 is described. FIG. 5 is a flowchart of a method of manufacturing light-emitting apparatus 10. FIG. 6A to FIG. 6E are cross-sectional views each illustrating one step in a method of manufacturing light-emitting apparatus 10. Note that FIG. 6A to FIG. 6E are views corresponding to FIG. 4.

First, as illustrated in FIG. 6A, buffer layer 14 is formed on substrate 11 on which wiring 16 has been formed in advance (Step S11). Specifically, buffer layer 14 is formed as follows.

First, a solvent is added to fritted glass in powder form (powdery glass), and the resultant is kneaded to prepare paste for forming buffer layer 14.

Next, the paste for forming buffer layer 14 is printed in a predetermined shape at a predetermined position on substrate 11. In Embodiment 1, the paste is printed in a circular annular shape so as to surround two or more LED chips 12. Note that the paste for forming buffer layer 14 may be applied instead of being printed.

Next, substrate 11 on which the paste for forming buffer layer 14 has been printed is sintered. As a result of substrate 11 being sintered, a glass frit in the paste for forming buffer layer 14 is softened, forming a glass-sintered film as buffer layer 14 on substrate 11 or wiring 16 as illustrated in FIG. 6B.

After buffer layer 14 is formed, dam member 15 is formed on the top surface of buffer layer 14 as illustrated in FIG. 6C (Step S12). Dam member 15 is formed in a circular annular shape as is buffer layer 14. A dispenser that releases a white resin is used to form dam member 15.

Next, two or more LED chips 12 are mounted on substrate 11 as illustrated in FIG. 6D (Step S13). A die-attach material or the like is used to mount LED chips 12 by die bonding. At this time, two or more LED chips 12 are electrically connected to each other by bonding wire 17 and wiring 16.

Next, as illustrated in FIG. 6E, second sealing member 18 is formed on substrate 11 so as to individually cover second LED chip 12r among two or more LED chips 12 (Step S14).

First sealing member 13 fills (is applied to) the inside as illustrated in FIG. 4 (Step S15). Specifically, a light-transmissive resin material containing yellow phosphor particles and green phosphor particles is injected into the region surrounded by dam member 15 and then is cured by heating, light irradiation, or the like.

### Advantageous Effects, Etc.

As described above, according to the present embodiment, second sealing member 18 sealing second LED chip 12r is located between second LED chip 12r and first sealing member 13. Therefore, the red light emitted from second LED chip 12r passes through second sealing member 18 before passing through first sealing member 13. This means that it is possible to shorten a path of the red light passing through first sealing member 13 by the length of the path over which the red light passes through second sealing member 18, allowing the red light to be less absorbed by first sealing member 13. Furthermore, since the absorbance of second sealing member 18 is lower than that of first sealing member 13, the light-emission intensity of the red light passing through second sealing member 18 is less likely to be reduced than that of the red light passing through first sealing member 13. For the foregoing reasons, the decrease in light-emission intensity of red light can be reduced, and thus it is possible to provide desired color rendering properties.

Furthermore, even light-emitting apparatus 10 in which the region surrounded by dam member 15 is filled with first sealing member 13, that is, light-emitting apparatus 10 having what is called a dam structure, is capable of reducing the decrease in light-emission intensity of red light.

Furthermore, since second sealing member 18 is in the shape of a hemisphere, the red light that has entered second sealing member 18 from second LED chip 12r can be output through a spherical surface of second sealing member 18 without being totally reflected off the spherical surface. Thus, the decrease in light-emission intensity of the red light emitted from second LED chip 12r can further be reduced.

Furthermore, since second sealing member 18 includes a transparent resin that does not contain a phosphor, the absorbance of second sealing member 18 can be as low as possible. Therefore, the light-emission intensity of the red light passing through second sealing member 18 can further be maintained.

Furthermore, since first sealing member 13 seals second sealing member 18, the phosphors (yellow phosphor particles and green phosphor particles) are present above second sealing member 18 as well. Therefore, these phosphors emit white light by being excited by the bluelight traveling above second sealing member 18, and thus it is possible to reduce the occurrence of white light being unevenly output.

### Variations

Above Embodiment 1 has described an example where first sealing member 13 seals second sealing member 18. However, a portion of second sealing member 18 may be exposed from first sealing member 13.

FIG. 7 is a cross-sectional view of light-emitting apparatus 10A according to a variation, schematically illustrating a configuration thereof. Specifically, FIG. 7 is a view corresponding to FIG. 4. In the following descriptions, elements that are identical to those in light-emitting apparatus 10 according to Embodiment 1 described above are assigned the same reference signs, and there are cases where descriptions thereof are omitted.

As illustrated in FIG. 7, first sealing member 13a in light-emitting apparatus 10A is formed on substrate 11 so as to have a smaller thickness as a whole than the thickness of second sealing member 18 at the apex portion thereof. Thus, with the entire circumference of second sealing member 18 in a plan view being surrounded by first sealing member 13a, the apex portion of second sealing member 18 is exposed from first sealing member 13a. The apex portion exposed from first sealing member 13a is a surface region of second sealing member 18 that includes a portion through which the optical axis of second LED chip 12r passes.

Since the apex portion of second sealing member 18 is exposed from first sealing member 13a as just described, most of the red light emitted from second LED chip 12r is output without passing through first sealing member 13a. Thus, the absorption of red light by first sealing member 13 can be significantly reduced, and the decrease in light-emission intensity of red light can further be reduced. The red light, output from second sealing member 18 and the white light output from first sealing member 13a are mixed outside of light-emitting apparatus 10A, resulting' in white light having improved color rendering properties.

Note that although first sealing member 13a is formed so as to have a smaller thickness as a whole than the thickness of second sealing member 18 to expose the apex portion of second sealing member 18 in the present variation, first sealing member 13 may be formed so as to have a larger thickness than the thickness of second sealing member 18. In this case, the first sealing member is only required to have an opening through which the apex portion of second sealing member 18 is exposed.

### Embodiment 2

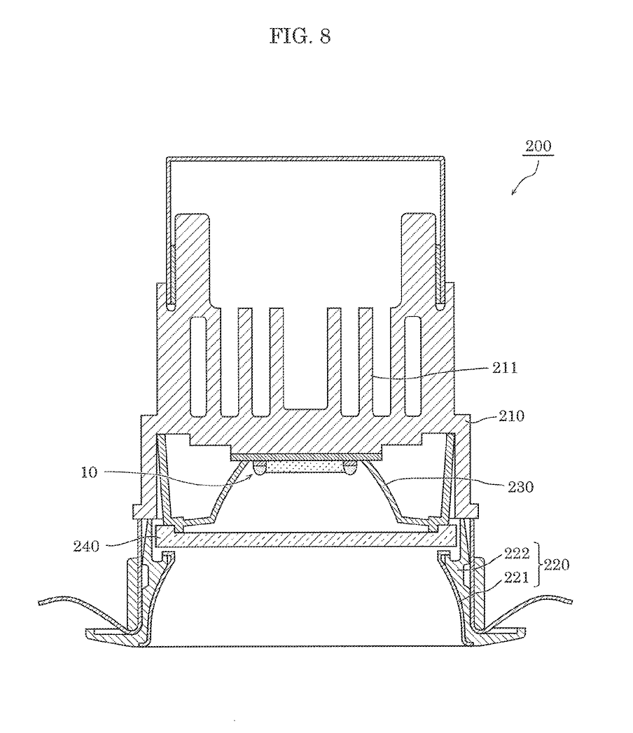

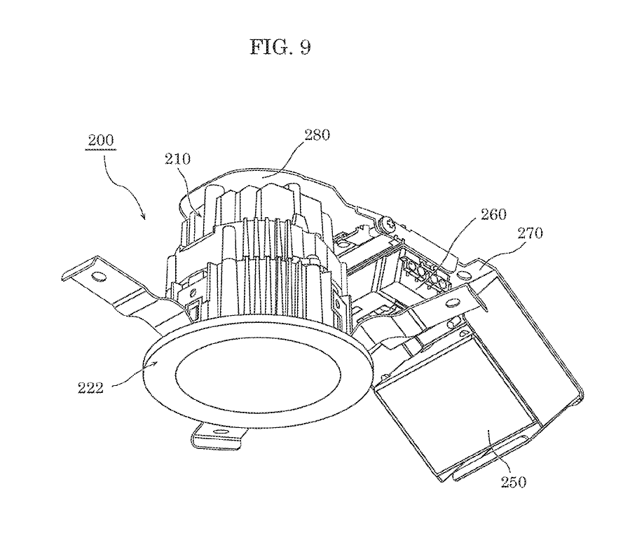

Next, illumination apparatus 200 according to Embodiment 2 is described with reference to FIG. 8 and FIG. 9. FIG. 8 is a cross-sectional view of illumination apparatus 200 according to Embodiment 2, FIG. 9 is a perspective view of external appearances of illumination apparatus 200 and peripheral members thereof according to Embodiment 2.

As illustrated in FIG. 8 and FIG. 9, illumination apparatus 200 according to Embodiment 2 is a sunken illumination apparatus, such as a recessed light, that emits light downward (toward the floor or a wall, for example) by being installed, for example, in the ceiling of a house.

Illumination apparatus 200 includes light-emitting apparatus 10. Illumination apparatus 200 further includes an apparatus body in the shape of a substantial bottomed tube formed by joining pedestal 210 and frame 220, and reflection plate 230 and light-transmissive panel 240 disposed on this apparatus body.

Pedestal. 210 is an attachment base to which light-emitting apparatus 10 is attached, and also serves as a heat sink for dissipating heat generated by light-emitting apparatus 10. Pedestal 210 is formed into a substantially columnar shape using a metal material and is, in Embodiment 2, made of die-cast aluminum.

Two or more heat-dissipating fins 211 are provided at predetermined intervals along one direction on the top portion (ceiling-side portion) of pedestal 210 so as to protrude upward. With this, heat generated by light-emitting apparatus 10 can be efficiently dissipated.

Frame 220 includes: cone portion 221 including a reflective surface on an inner surface and having a substantially circular tube shape and frame body 222 to which cone portion 221 is attached. Cone portion 221 is formed using a metal material and can for example, be formed of an aluminum alley or the like by metal spinning or pressing. Frame body 222 is formed of a hard resin material or a metal material. Frame 220 is fixed by frame body 222 being attached to pedestal 210.

Reflection plate 230 is a circular-annular-frame-shaped (funnel-shaped) reflection member having an inner surface reflection function. For example, reflection plate 230 can be formed using a metal material such as aluminum. Note that reflection plate 230 may be formed using a hard white resin material instead of a metal material.

Light-transmissive panel 240 is a light-transmissive member having light-diffusing properties and light-transmitting properties. Light-transmissive panel 240 is a flat plate disposed between reflection plate 230 and frame 220, and is attached to reflection plate 230. For example, light-transmissive panel 240 can be formed into a disc shape using a transparent resin material such as acrylic or polycarbonate.

Note that illumination apparatus 200 is not required to include light-transmissive panel 240. Without light-transmissive panel 240, illumination apparatus 200 allows an improvement in the luminous flux of light that is emitted therefrom.

Furthermore, as illustrated in FIG. 9, lighting apparatus 250 which supplies lighting power to light-emitting apparatus 10, and terminal base 260 which relays AC power from a commercial power supply to lighting apparatus 250 are connected to illumination apparatus 200.

Lighting apparatus 250 and terminal base 260 are fixed to attachment plate 270 provided separately from the apparatus body. Attachment plate 270 is formed by folding a rectangular plate member made of a metal material, and has one longitudinal end the bottom surface of which lighting apparatus 250 is fixed to and the other longitudinal end the bottom surface of which terminal base 260 is fixed to. Attachment plate 270 is connected together with top plate 280 which is fixed to a top portion of pedestal 210 of the apparatus body.

In illumination apparatus 200 as a result of including light-emitting apparatus 10, the decrease in light-emission intensity of red light is reduced. Thus, it can be said that illumination apparatus 200 can provide desired color rendering properties.

Although the illumination apparatus is exemplified as a recessed light in Embodiment 2, the illumination apparatus according to the present disclosure may be implemented as a spotlight or a different illumination apparatus.

### Other Embodiments

Although light-emitting apparatus 10 and illumination apparatus 200 according to the embodiments have been described above, the present disclosure is not limited to the above-described embodiments.

Furthermore, although buffer layer 14 and dam member 15 are each formed in an annular shape so as to surround LED chip 12 in the above embodiments, the shape, etc., of buffer layer 14 and dam member 15 is not particularly limited. Moreover, buffer layer 14 is not required to be provided; dam member 15 may be formed directly on substrate 11.

Furthermore, in the above embodiments, white light is output using a combination of first LED chip 12b that emits blue light with the yellow phosphor particles and the green phosphor particles, but the configuration for outputting white light is not limited to that described above. For example, an ultraviolet LED chip that outputs ultraviolet light having a wavelength shorter than that of light output from first LED chip 12b may be combined with blue phosphor particles, yellow phosphor particles, and green phosphor particles that output blue light, yellow light, and green light, respectively as a result of being excited mainly by ultraviolet light.

Furthermore, in the above embodiments, the light-emitting element that is not intended to excite a phosphor is exemplified as second LED chip 12r which emits red light. However, a second LED chip which emits light of another color can be used as long as the second LED chip is not intended to excite a phosphor. In this case, it is desired that first sealing member 13 does not contain the phosphor that is excited by the light of another color, but even if first sealing member 13 contains such a phosphor, the decrease in the light-emission intensity can be reduced because the second LED chip is sealed with the second sealing member.

Furthermore, in the above embodiments, LED chip 12 mounted on substrate 11 is connected to another LED chip 12 in a chip-to-chip configuration by bonding wire 17. However, LED chip 12 may be connected by bonding wire 17 to wiring 16 (a metal film) provided on substrate 11, and thus electrically connected to another LED chip 12 via wiring 16.

Furthermore, the light-emitting element to be used in light-emitting apparatus 10 is exemplified as LED chip 12 in the above embodiments. However, a semiconductor light-emitting element such as a semiconductor laser, or another type of solid-state light-emitting element, such as an electroluminescent (EL) element including an organic or inorganic EL material, may be used as the light-emitting element.

Furthermore, the configuration in the present disclosure can also be applied to a line module in which light-emitting elements are linearly mounted in one line only.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What, is claimed is:

1. A light-emitting apparatus comprising:
a substrate;
a first light-emitting element mounted on the substrate;
a second light-emitting element having a light-emission peak wavelength longer than a light-emission peak wavelength of the first light-emitting element;
a first sealing member sealing the first light-emitting element and containing a phosphor that emits fluorescent light when illuminated by light from the first light-emitting element; and
a second sealing member sealing the second light-emitting element and having at least a portion between the first sealing member and the second light-emitting element,
wherein the second sealing member has an absorbance lower than an absorbance of the first sealing member with respect to light emitted from the second light-emitting element.

2. The light-emitting apparatus according to claim 1, further comprising
a dam member provided on the substrate and surrounding the first light-emitting element and the second light-emitting element.
wherein the first sealing member fills a region surrounded by the dam member.

3. The light-emitting apparatus according to claim 1,
wherein the second sealing member is hemispherical.

4. The light-emitting apparatus according to claim 1,
wherein the second sealing member includes a transparent resin that does not contain the phosphor.

5. The light-emitting apparatus according to claim 1,
wherein the first sealing member seals the second sealing member.

6. The light-emitting apparatus according to claim 1,
wherein the second sealing member is exposed from the first sealing member in a surface region including a portion through which an optical axis of the second light-emitting element passes.

7. The light-emitting apparatus according to claim 1,
wherein the first light-emitting element is a blue light-emitting diode (LED) which emits blue light, and
the second light-emitting element is a red LED winch emits red light.

8. An illumination apparatus comprising
the light-emitting apparatus according to claim 1.

9. A light-emitting apparatus comprising:
a substrate;
first light-emitting elements disposed on the substrate, the first light emitting elements emitting first light having a first light-emission peak wavelength;
second light-emitting elements disposed on the substrate, the second light-emitting elements emitting second light having a second light-emission peak wavelength longer than the first light-emission peak wavelength;
a first sealing member sealing the first light-emitting elements and containing a phosphor that emits fluorescent light when illuminated by the first light; and
second sealing members sealing the second light-emitting elements, respectively,
wherein the first seaming member covers at least a portion of each of the second sealing members and is not in contact with second light-emitting elements, and
the second sealing members have an absorbance lower than an absorbance of the first sealing member with respect to the second light.

10. The light-emitting apparatus according to claim 9,
wherein the first light is blue light, and
the second light is red light.

11. The light-emitting apparatus according to claim 9,
wherein the second sealing members are fully embedded in the first sealing member.

12. A light-emitting apparatus comprising:
a substrate;
a first light-emitting element disposed on the substrate, the first light emitting element emitting first light having a first light-emission peak wavelength;
a second light-emitting element disposed on the substrate, the second light-emitting element emitting second light having a second light-emission peak wavelength than the first light-emission peak wavelength;
a first sealing member sealing the first light-emitting element and containing a phosphor that emits fluorescent light when illuminated by the first light; and
a second sealing member sealing the second light-emitting element,
wherein at least a portion of the second sealing member is disposed between the first sealing member and the second light-emitting element, and the second sealing member includes a transparent resin that does not contain the phosphor.

13. The light-emitting apparatus according to claim 12,
wherein the first light is blue light, and
the second light is red light.

14. The light-emitting apparatus according to claim 12,
wherein the second sealing member is fully embedded in the first sealing member.
